(19) United States
(12) Patent Application Publication
(10) Pub. No.: US 2016/0079510 A1
(43) Pub. Date: Mar. 17, 2016

(54) CASCADE THERMOELECTRIC MODULE CONFIGURABLE FOR EITHER COMMON OR SEPARATE POWER

(71) Applicant: Phononic Devices, Inc., Durham, NC (US)

(72) Inventors: Devon Newman, Morrisville, NC (US); Abhishek Yadav, Cary, NC (US); Arthur Prejs, Cary, NC (US); Ravi Kiran Chilukuri, Cary, NC (US)

(21) Appl. No.: 14/865,874

(22) Filed: Sep. 25, 2015

Related U.S. Application Data
(63) Continuation of application No. PCT/US2015/050417, filed on Sep. 16, 2015.
(60) Provisional application No. 62/050,824, filed on Sep. 16, 2014.

(51) Int. Cl. H01L 35/32

(52) U.S. Cl. CPC H01L 35/325

(57) ABSTRACT

Embodiments described herein include a cascade Thermoelectric Module (TEM) that includes at least three headers. A first header and a first surface of a second header electrically connect first legs to form a stage of thermoelectric devices electrically connected in series, and define first and second leg placement positions for a subset of the first legs. A second surface of the second header and a third header electrically connect second legs to form another stage of thermoelectric devices electrically connected in series, and define first and second leg placement positions for a subset of the second legs. The stages are electrically coupled in series when the subsets of the first and second legs are positioned in their respective first leg placement positions, and the stages are electrically decoupled when the subsets of the first and second legs are positioned in their respective second leg placement positions.

### RELATED APPLICATIONS

This application is a continuation of International application serial number PCT/US2015/050417, filed Sep. 16, 2015, which claims the benefit of provisional patent application Ser. No. 62/050,824, filed Sep. 16, 2014, the disclosures of which are hereby incorporated herein by reference in their entireties.

### FIELD OF THE DISCLOSURE

The present disclosure relates to a cascade Thermoelectric Module (TEM) including headers that enable stages of the cascade TEM to be configured for either common or separate power.

### BACKGROUND

Thermoelectric devices are solid state semiconductor devices that, depending on the particular application, can be either Thermoelectric Coolers (TECs) or Thermoelectric Generators (TEGs). TECs are solid state semiconductor devices that utilize the Peltier effect to transfer heat from one side of the device to the other, thereby creating a cooling effect on the cold side of the device. Because the direction of heat transfer is determined by the polarity of an applied voltage, thermoelectric devices can be used generally as temperature controllers. Similarly, TEGs are solid state semiconductor devices that utilize the Seebeck effect to convert heat (i.e., a temperature difference from one side of the device to the other) directly into electrical energy. One example of a thermoelectric device that is configured as a TEC is illustrated in FIG. 1. Notably, as used herein, a thermoelectric device consists of a single N-type leg and a single P-type leg (i.e., is a two-leg device), whereas a Thermoelectric Module (TEM) includes many thermoelectric devices.

As illustrated in FIG. 1, a thermoelectric device 10 includes an N-type leg 12, a P-type leg 14, a top conductive metal layer 16, and a bottom conductive metal layer 18. The N-type leg 12 and the P-type leg 14 are formed of a thermoelectric material (i.e., a semiconductor material having sufficiently strong thermoelectric properties). In order to effect thermoelectric cooling, an electrical current is applied to the thermoelectric device 10 as shown. The direction of current transference in the N-type leg 12 and the P-type leg 14 is parallel to the direction of heat transference in the thermoelectric device 10. As a result, cooling occurs at the top conductive metal layer 16 by absorbing heat at the top surface of the thermoelectric device 10 and releasing the heat at the bottom surface of the thermoelectric device 10.

One example of a Thermoelectric Module (TEM) is illustrated in FIG. 2. As illustrated, a TEM 20 includes multiple thermoelectric devices 10-1 through 10-10 (generally referred to herein collectively as thermoelectric devices 10 and individually as thermoelectric device 10) connected in series. These multiple thermoelectric devices 10 are packaged within the single TEM 20. In some applications, multiple TEMs can be cascaded together to achieve a greater cooling effect.

Thermoelectric systems that use TEMs are advantageous compared to non-thermoelectric systems because they lack moving mechanical parts, have long lifespans, and can have small sizes and flexible shapes. However, existing TEMs lack flexibility to satisfy the diverse demands of different applications. As such, thermoelectric systems remain cost-prohibitive because, for example, different types of TEMs must be designed and produced for different applications. Accordingly, there remains a need for a flexible TEM that satisfies the demands of different applications while reducing the high costs associated with providing such flexibility.

### SUMMARY

Systems, devices, and methods are disclosed herein relating to a cascade Thermoelectric Module (TEM) (i.e., a multistage cascade TEM). In some embodiments, a cascade TEM comprises a plurality of headers comprising a first header, a second header, and a third header. The first header and a first surface of the second header are configured to electrically connect a first plurality of legs to form a first stage of thermoelectric devices electrically connected in series. The first header and the first surface of the second header define a first set of leg placement positions for a subset of the first plurality of legs and a second set of leg placement positions for the subset of the first plurality of legs. A second surface of the second header and the third header are configured to electrically connect a second plurality of legs to form a second stage of thermoelectric devices electrically connected in series. The second surface of the second header and the third header define a first set of leg placement positions for a subset of the second plurality of legs and a second set of leg placement positions for the subset of the second plurality of legs. The second header is further configured such that the first and second stages of thermoelectric devices are electrically coupled in series when the subsets of the first and second pluralities of legs are positioned in the respective first sets of leg placement positions, and the first and second stages of thermoelectric devices are electrically decoupled within the TEM when the subsets of the first and second pluralities of legs are positioned in the respective second sets of leg placement positions.

In this manner, the cascade TEM can provide improved efficiencies compared to existing TEMs by utilizing multiple cascade stages that can operate together or separately, depending on the positioning of the subsets of the first and second pluralities of legs. Moreover, the cascade TEM architecture reduces costs of manufacturing and production because of its flexible design that enables multiple stages to be powered together or separately by simply altering leg placement within the same header design.

In some embodiments, the first header further comprises a first plurality of pads and defines leg placement positions for first ends of the first plurality of legs of the first stage of thermoelectric devices connected to the first plurality of pads.

In some embodiments, the second header further comprises a second plurality of pads on the first side of the second header. The second plurality of pads defines leg placement positions for second ends of the first plurality of legs of the first stage of thermoelectric devices connected to the second plurality of pads such that the first stage of thermoelectric devices are connected in series by the first and second pluralities of pads of the first header and the first side of the second header, respectively. A third plurality of pads on the second side of the second header defines leg placement positions for first ends of the second plurality of legs of the second stage of thermoelectric devices connected to the third plurality of pads.

In some embodiments, the third header further comprises a fourth plurality of pads that define leg placement positions for second ends of the second plurality of legs of the second stage of thermoelectric devices connected to the fourth plurality of pads such that the second stage of thermoelectric devices are connected in series by the third and fourth pluralities of pads of the second side of the second header and the third header, respectively.

In some embodiments, the first plurality of pads comprise pads that each define one of the first set of leg placement positions and one of the second set of leg placement positions for the first ends of the subset of the first plurality of legs. Each pad of the first plurality of pads further defines a leg placement position for the first end of an additional leg of the first plurality of legs. The second plurality of pads comprise pads that each define one of the first set of leg placement positions for the second end of one of the subset of the first plurality of legs and an additional pad that defines the second set of leg placement positions for the second ends of the subset of the first plurality of legs. The third plurality of pads comprise pads that each define one of the first set of leg placement positions for the first end of one of the subset of the second plurality of legs, and pads that each define one of the second set of leg placement positions for the first end of one of the subset of the second plurality of legs. The fourth plurality of pads comprise pads that each define one of the first set of leg placement positions and one of the second set of leg placement positions for the second ends of the subset of the second plurality of legs. Each pad of the plurality of pads further defines a leg placement position for the second end of an additional leg of the second plurality of legs.

In some embodiments, the second header comprises vias that electrically couple the pads that define the first leg placement positions on the first side of the second header and the pads that define the first leg placement positions on the second side of the second header such that, when the subsets of the first and second pluralities of legs are positioned in the respective first sets of leg placement positions, the first and second stages of thermoelectric devices are electrically coupled in series by the vias through the second header.

In some embodiments, the first header further comprises positive and negative contact pads for the first stage of thermoelectric devices and the second header further comprises positive and negative contact pads for the second stage of thermoelectric devices. When the subsets of the first and second pluralities of legs are positioned in the respective second sets of leg placement positions, the cascade TEM is operated in a common power mode of operation by electrically coupling the positive contact pad of one of the first and second stages to the negative contact pad of the other one of the first and second stages.

In some embodiments, the subsets of the first and second pluralities of legs are positioned in the respective first sets of leg placement positions such that the first and second stages of thermoelectric devices are electrically coupled in series.

In some embodiments, the subsets of the first and second pluralities of legs are positioned in the respective second sets of leg placement positions such that the first and second stages of thermoelectric devices are electrically decoupled within the cascade TEM.

In some embodiments, the cascade TEM further comprises the first plurality of legs and the second plurality of legs, wherein each of the first plurality of legs has equivalent first dimensions and each of the second plurality of legs has equivalent second dimensions different from the first dimensions of the first plurality of legs.

In some embodiments, the cascade TEM further comprises the first plurality of legs and the second plurality of legs, wherein a total number of the first plurality of legs is different than a total number of the second plurality of legs.

In some embodiments, the cascade TEM further comprises the first plurality of legs and the second plurality of legs, wherein a total number of the first plurality of legs is different than a total number of the second plurality of legs such that the cascade TEM forms a pyramidal shaped structure.

Embodiments of a thermoelectric system are also disclosed. In some embodiments, the thermoelectric system comprises a cascade TEM and a control system configured to power the cascade TEM in accordance with one or more modes of operation. The cascade TEM comprises a plurality of headers comprising a first header, a second header, and a third header. The first header and a first surface of the second header are configured to electrically connect a first plurality of legs to form a first stage of thermoelectric devices electrically connected in series. The first header and the first surface of the second header define a first set of leg placement positions for a subset of the first plurality of legs and a second set of leg placement positions for the subset of the first plurality of legs. A second surface of the second header and the third header are configured to electrically connect a second plurality of legs to form a second stage of thermoelectric devices electrically connected in series. The second surface of the second header and the third header define a first set of leg placement positions for a subset of the second plurality of legs and a second set of leg placement positions for the subset of the second plurality of legs. The second header is further configured such that the first and second stages of thermoelectric devices are electrically coupled in series when the subsets of the first and second pluralities of legs are positioned in the respective first sets of leg placement positions. The first and second stages of thermoelectric devices are electrically decoupled within the cascade TEM when the subsets of the first and second pluralities of legs are positioned in the respective second sets of leg placement positions.

In some embodiments, the subsets of the first and second pluralities of legs are positioned in the respective first sets of leg placement positions such that the first and second stages of thermoelectric devices are electrically coupled in series.

In some embodiments, the subsets of the first and second pluralities of legs are positioned in the respective second sets of leg placement positions such that the first and second stages of thermoelectric devices are electrically decoupled within the cascade TEM.

In some embodiments, the first header further comprises a set of contact pads configured to receive power from a first power source coupled to a positive one of the set of contact pads and a negative one of the set of contact pads. The second header further comprises a set of contact pads configured to receive power from a second power source coupled to a positive one of the set of contact pads and a negative one of the set of contact pads. The thermoelectric system further comprises one or more electrical connectors configured to electrically couple one of the set of contact pads of the first header and one of the set of contact pads of the second header to electrically couple the first and second stages of thermoelectric devices in series.

In some embodiments, the control system further comprises power control and switching circuitry configured to selectively activate or deactivate the one or more electrical connectors in accordance with the one or more modes of operation.

In some embodiments, the control system further comprises a controller configured to select one of the one or more modes of operation to thereby provide a selected mode of operation and control the power control switching circuitry to selectively activate or deactivate the one or more electrical connectors in accordance with the one or more modes of operation.

In some embodiments, the selected mode of operation is selected from a group consisting of an external common power mode of operation in which the one or more electrical connectors connect one of the set of contact pads of the first header and one of the set of contact pads of the second header to electrically couple the first and second stages of thermoelectric devices in series. The first and second stages of thermoelectric devices are powered by a common power source, a first separate power mode of operation in which the first and second stages of thermoelectric devices are configured to be powered from a single power source in parallel, and a second separate power mode of operation in which the first stage of thermoelectric devices and the second stage of thermoelectric devices are powered by distinct power sources.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a thermoelectric device configured as a Thermoelectric Cooler (TEC);

FIG. 2 illustrates a Thermoelectric Module (TEM) including multiple thermoelectric devices;

FIG. 3 illustrates a cascade TEM including an upper stage of thermoelectric devices and a lower stage of thermoelectric devices;

FIG. 4A illustrates a cascade TEM including subsets of legs in lower and upper stages of thermoelectric devices positioned in first leg placement positions that provide a common power configuration for the cascade TEM in which the lower and upper stages are configured to be powered by a common power source according to some embodiments of the present disclosure;

FIG. 4B illustrates the cascade TEM of FIG. 4A including the subsets of the legs in the lower and upper stages of thermoelectric devices positioned in second leg placement positions that provide a separate power configuration for the cascade TEM in which the lower and upper stages are configured to be powered separately according to some embodiments of the present disclosure;

FIG. 5 illustrates a bottom header of the cascade TEM of FIGS. 4A and 4B according to some embodiments of the present disclosure;

FIGS. 6A and 6B illustrate a bottom and a top surface of an intermediate (e.g., middle) header, respectively, of the cascade TEM of FIGS. 4A and 4B according to some embodiments of the present disclosure;

FIG. 7 illustrates a top header of the cascade TEM of FIGS. 4A and 4B according to some embodiments of the present disclosure;

FIGS. 8A through 8D illustrate portions of the bottom header, the bottom surface of the intermediate header, the top surface of the intermediate header, and the top header, respectively, including the subsets of legs in the lower and upper stages of thermoelectric devices positioned in the first leg placement positions that provide the common power configuration of the cascade TEM according to some embodiments of the present disclosure;

FIGS. 9A through 9D illustrate portions of the bottom header, the bottom surface of the intermediate header, the top surface of the intermediate header, and the top header, respectively, including the subsets of legs in the lower and upper stages of thermoelectric devices positioned in the second leg placement positions that provide the separate power configuration of the cascade TEM according to some embodiments of the present disclosure;

FIG. 10 illustrates the series connection of the thermoelectric devices in the lower and upper stages of thermoelectric devices by vias through the intermediate header when the cascade TEM is configured in the common power configuration according to some embodiments of the present disclosure;

FIG. 11 illustrates the electrical decoupling of the thermoelectric devices in the lower and upper stages of thermoelectric devices when the cascade TEM is configured in the separate power configuration according to some embodiments of the present disclosure;

FIG. 12 illustrates an embodiment in which an external electrical connector is utilized to electrically connect the lower and upper stages of thermoelectric devices of the cascade TEM shown in FIG. 11 in series to form an external common power mode of operation according to some embodiments of the present disclosure;

FIGS. 13A through 13C illustrate different modes of operation for the cascade TEM according to some embodiments of the present disclosure;

FIG. 14 is a block diagram of a thermoelectric system including a control system and a cascade TEM(s) in which a controller and power control and switching circuitry of the control system selectively supply power to the cascade TEM(s) in accordance with the different modes of operation according to some embodiments of the present disclosure;

FIG. 15 is a graph illustrating Coefficient of Performance (COP) curves for a cascade TEM controlled by the control system of FIG. 14 to utilize a common (i.e., serial) operation or a separate operation according to some embodiments of the present disclosure;

FIGS. 16A through 16D illustrate various constructions of a cascade TEM utilizing different leg structures according to some embodiments of the present disclosure;

FIGS. 17A through 17D are graphs illustrating optimizations of a number of legs for the upper stage of the cascade TEM to obtain a maximum increase in COP depending on a ΔT according to some embodiments of the present disclosure; and

FIGS. 18A and 18B are graphs illustrating performance curves for common (e.g., serial) connectivity of a cascade TEM according to some embodiments of the present disclosure.

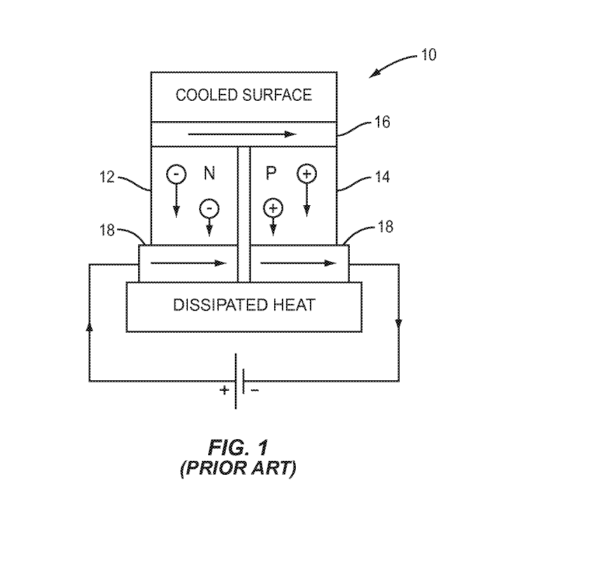

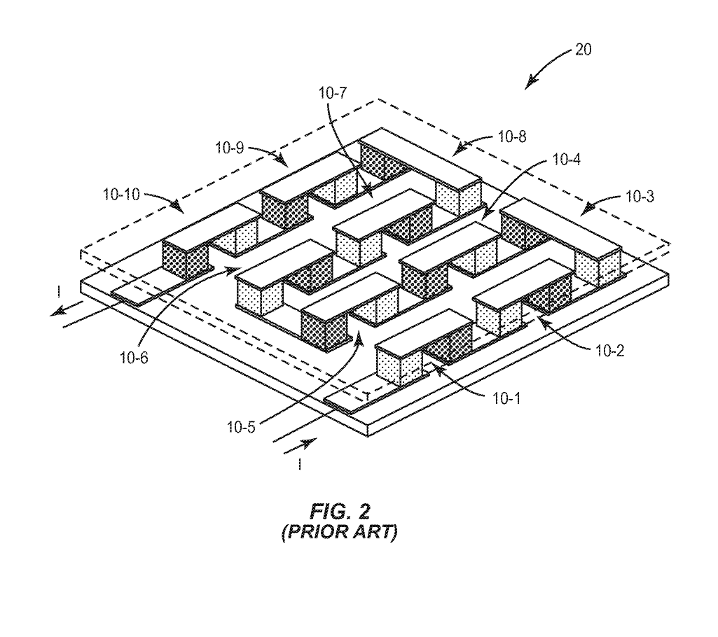

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Systems, devices, and methods are disclosed herein relating to a cascade Thermoelectric Module (TEM) (i.e., a multistage cascade TEM). However, before describing embodiments of these systems, devices, and methods, a discussion of existing TEM architectures and conventional power controls systems is beneficial.

The performance of a TEM is constrained by its architecture. For example, the number of thermoelectric devices in a TEM constrains the maximum temperature differential (ΔT) across the TEM for heat transfer. As such, heat pumped by inputting power to the TEM is limited by the maximum ΔT. Existing thermoelectric systems use control systems to provide power in accordance with a fixed operational behavior of a specific TEM architecture. To achieve a higher ΔT, multiple TEMs can be stacked as cascade stages to obtain greater heat transfer across the cascade TEM. In some applications, it is desirable for the cascaded TEMs to be electrically coupled in series and powered by a common power source. However, in other applications, it is desirable for the cascaded TEMs to be electrically decoupled and be powered separately (e.g., by separate power sources or by a common power source in parallel).

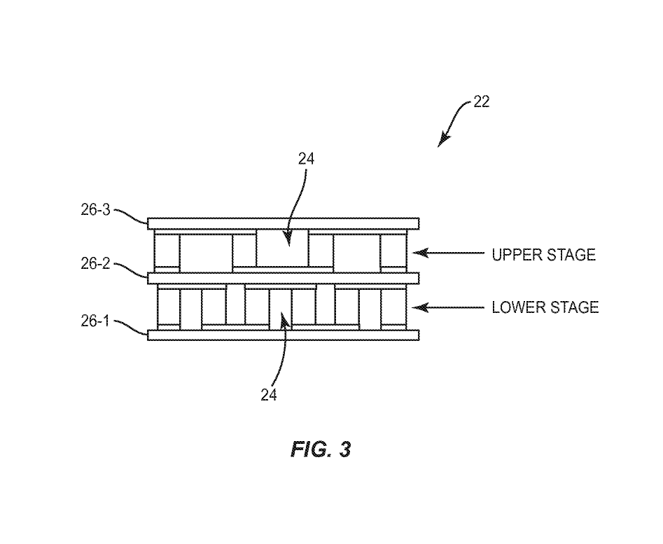

Rather than cascading multiple TEMs, there is a desire to achieve the same effect in a single TEM. In particular, as illustrated in FIG. 3, rather than cascading multiple TEMs, a single cascade TEM 22 may be used. As illustrated, the single cascade TEM 22 includes multiple stages, or layers, of thermoelectric devices 24 and headers 26-1, 26-2, and 26-3 (generally referred to herein collectively as header 26 and individually as headers 26) that provide the electrical connections for the thermoelectric devices 24 in the respective stages. As discussed above, in some applications, it is desirable for the stages of thermoelectric devices to be electrically connected in series and powered by a common power source. In other applications, it is desirable for the stages of thermoelectric devices to be electrically decoupled and separately powered. Thus, using conventional techniques, different cascade TEMs, and in particular different headers for cascade TEMs, must be designed and manufactured for different applications.

The present disclosure overcomes these drawbacks with a cascade TEM (i.e., a multistage cascade TEM) that can be configured for either common or separate power for the stages of thermoelectric devices in the cascade TEM. In some embodiments, the disclosed cascade TEM includes a layout that allows subsets of legs (e.g., a single pair) in the respective stages to have two possible placement positions. When the subsets of legs are positioned in one placement position, the stages of thermoelectric devices are electrically coupled in series such that they are configured to be powered by a common power source. The series connection between the stages of thermoelectric devices provides a serial path of electrical continuity that traverses any order of the thermoelectric devices of the stages of the cascade TEM. This configuration is referred to herein as a “common power configuration.” When the cascade TEM is configured in the common power configuration and is in operation, the cascade TEM is referred to herein as operating in a “common power mode” or “common power mode of operation.”

When the subsets of legs are positioned in the other placement position, the stages of thermoelectric devices are electrically decoupled such that they are configured to be separately powered. This configuration is referred to herein as a “separate power configuration.” When the cascade TEM is configured in the separate power configuration and is in operation, the cascade TEM is referred to herein as operating in a “separate power mode” or “separate power mode of operation.” As such, embodiments of the disclosed cascade TEM architecture are flexible because placing the subsets of legs at one of two leg placement positions results in different configurations and operational behaviors for the cascade TEM. This provides reduced costs for the design and manufacture of the cascade TEM for different applications.

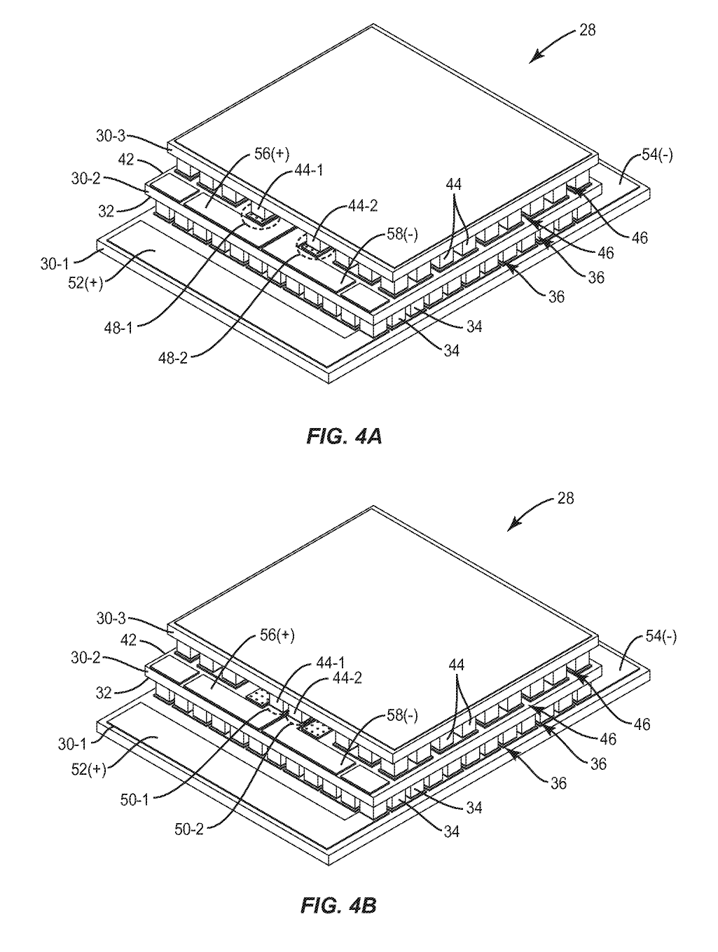

FIG. 4A illustrates a cascade TEM 28 (i.e., a multistage cascade TEM 28) configured in a common power configuration according to some embodiments of the present disclosure. FIG. 4B illustrates the cascade TEM 28 of FIG. 4A configured in a separate power configuration according to some embodiments of the present disclosure. In this example, the cascade TEM 28 includes a bottom header 30-1, an intermediate (e.g., middle) header 30-2, and a top header 30-3, which are generally referred to herein as headers 30. The bottom header 30-1 and a bottom surface 32 of the intermediate header 30-2 are configured to electrically connect thermoelectric legs 34 (simply referred to herein as legs 34) to form a lower stage of thermoelectric devices 36 that are electrically connected to one another in series. The bottom header 30-1 and the bottom surface 32 of the intermediate header 30-2 define both first leg placement positions 38-1 and 38-2 (not shown) for a subset of the legs 34, which are referred to as legs 34-1 and 34-2 (not shown), in the lower stage of thermoelectric devices 36 and second leg placement positions 40-1 and 40-2 (not shown) for the subset of the legs 34 (i.e., legs 34-1 and 34-2) in the lower stage of thermoelectric devices 36. The first and second leg placement positions 38 and 40 for the subset of the legs 34 in the lower stage of thermoelectric devices 36 are also referred to herein as first and second leg placement positions 38 and 40. As discussed below in detail, the first leg placement positions 38 are utilized for the common power configuration of the cascade TEM 28 (as illustrated in FIG. 4A), and the second leg placement positions 40 are utilized for the separate power configuration of the cascade TEM 28 (as illustrated in FIG. 4B).

An upper surface 42 of the intermediate header 30-2 and the top header 30-3 are configured to electrically connect legs 44 to form an upper stage of thermoelectric devices 46 that are electrically connected in series to one another. The upper surface 42 of the intermediate header 30-2 and the top header 30-3 define both first leg placement positions 48-1 and 48-2 and second leg placement positions 50-1 and 50-2 for a subset of the legs 44 in the upper stage of thermoelectric devices 46, where this subset of the legs 44 is referenced as legs 44-1 and 44-2. As discussed below in detail, the first leg placement positions 48-1 and 48-2 are utilized for the common power configuration of the cascade TEM 28 (as illustrated in FIG. 4A), and the second leg placement positions 50-1 and 50-2 are utilized for the separate power configuration of the cascade TEM 28 (as illustrated in FIG. 4B).

The bottom header 30-1 includes a positive contact pad 52 and a negative contact pad 54 (also referred to herein as contact pads 52 and 54) for powering at least the lower stage of the cascade TEM 28 by, for example, connecting a power source (e.g., current or voltage sources) to the positive contact pad 52 and the negative contact pad 54. The intermediate header 30-2 includes a positive contact pad 56 and a negative contact pad 58 (also referred to herein as contact pads 56 and 58) for powering the upper stage of the cascade TEM 28 by, for example, connecting a power source to the positive contact pad 56 and the negative contact 58.

As such, FIG. 4A shows a common power configuration in which the subset of the legs 34 (i.e., legs 34-1 and 34-2 in this example, which are not shown) in the lower stage of thermoelectric devices 36 are positioned in the first leg placement positions 38-1 and 38-2 and the subset of the legs 44 (i.e., legs 44-1 and 44-2 in this example) in the upper stage of thermoelectric devices 46 are also positioned in the respective first leg placement positions 48-1 and 48-2 such that the lower and upper stages of thermoelectric devices 36 and 46 are electrically coupled in series by vias through the intermediate header 30-2. Accordingly, in this example, connecting a single power source to the positive contact pad 52 and the negative contact pad 54 can power both stages of the cascade TEM 28 in series.

In contrast, FIG. 4B shows a separate power configuration in which the subset of the legs 34 (i.e., legs 34-1 and 34-2 in this example, which are not shown) in the lower stage of thermoelectric devices 36 are positioned in the second leg placement positions 40-1 and 40-2 (not shown) and the subset of the legs 44 (i.e., legs 44-1 and 44-2 in this example) in the upper stage of thermoelectric devices 46 are also positioned in the respective second leg placement positions 50-1 and 50-2 such that the lower and upper stages of thermoelectric devices 36 and 46 are electrically decoupled within the cascade TEM 28 (i.e., in this example, vias through the intermediate header 30-2 electrically couple the respective subsets of legs 34 and 44 when positioned at the first leg placement positions 38 and 48, but there are no vias through the intermediate header 30-2 to electrically couple the respective subsets of legs 34 and 44 when positioned at the second leg placement positions 40 and 50).

As such, the stages can be powered separately by distinct current sources (or the same current source in parallel, as detailed further below). For example, a first power source may be connected to the positive contact pad 52 and the negative contact pad 54 of the bottom header 30-1 to power the lower stage of thermoelectric devices 36, and a second current source may be connected to the positive contact pad 56 and the negative contact pad 58 of the intermediate header 30-2 to power the upper stage of thermoelectric devices 46 separately from the lower stage of thermoelectric devices 36. As such, the stages of the cascade TEM 28 can be operated independently when the cascade TEM 28 is configured in the separate power configuration.

The cascade TEM 28 thus enables each stage to be powered together or separately using the intermediate header 30-2 by varying the placement of the subsets of legs 34 and 44. This allows, for example, each stage to be operated at specific operating points to optimize performance. As detailed further below, in the example embodiments described herein, this is achieved by having a layout which allows a single pair of legs 34-1 and 34-2 in the lower stage of thermoelectric devices 36 and a single pair of legs 44-1 and 44-2 in the upper stage of thermoelectric devices 46 to have two possible placement positions. One leg position (i.e., the first leg placement positions 38 and 48) electrically couples the subsets of legs 34 and 44 using vias through the intermediate header 30-2 such that the lower and upper stages of thermoelectric devices 36 and 46, respectively, are electrically connected in series. The other leg position (i.e., the second leg placement positions 40 and 50) electrically decouples the lower and upper stages of thermoelectric devices 36 and 46, respectively, from one another.

Various details about the structure and materials used to construct a TEM are known to persons skilled in the art and, as such, have been omitted for brevity. For example, the headers may be ceramic headers or may be made of other or different materials. Moreover, the headers, legs, subsets of legs, stages, contacts, and various other components may be formed of materials having the appropriate electrical and/or thermal properties known by persons skilled in the art to be suitable for TEMs. As such, various details about materials that could be used to construct the cascade TEM 28 have been omitted because they are known to persons skilled in the art.

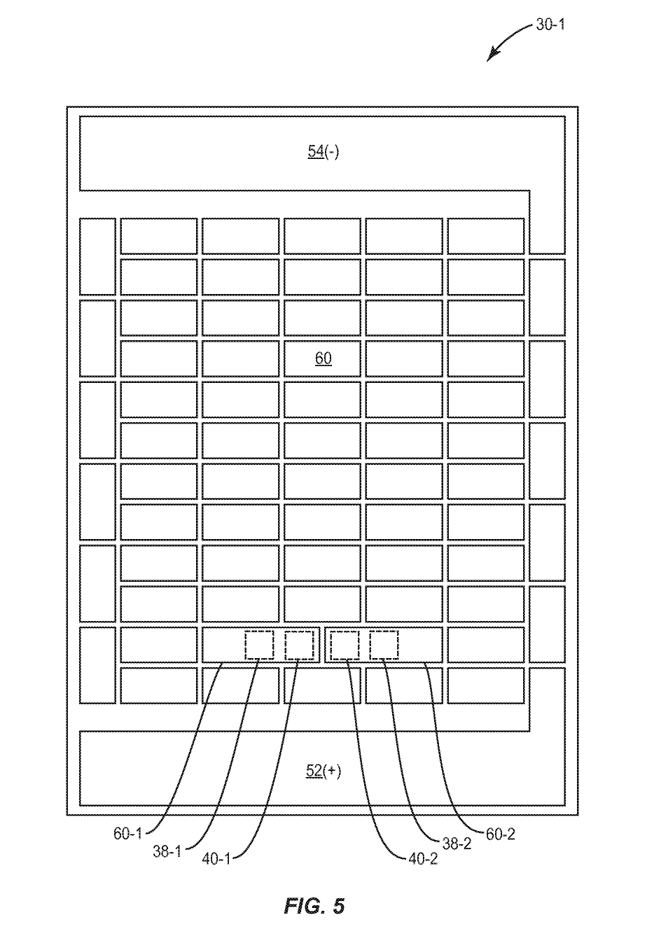

Referring back to the general construction of the cascade TEM 28 of FIGS. 4A and 4B, FIG. 5 illustrates the bottom header 30-1 in greater detail according to some embodiments of the present disclosure. As shown, the bottom header 30-1 includes multiple pads 60 that, together with corresponding pads on the bottom surface 32 (not shown) of the intermediate header 30-2 (not shown), electrically connect the legs 34 (not shown) to form the lower stage of thermoelectric devices 36 (not shown) that are electrically connected to one another in series. In particular, bottom ends of the legs 34 are electrically connected to corresponding locations on the pads 60, whereas top ends of the legs 34 are electrically connected to corresponding leg placement positions on the respective pads on the bottom surface 32 of the intermediate header 30-2.

Further, in this example, two of the pads 60, which are referenced as pads 60-1 and 60-2, are elongated pads that define both the first leg placement positions 38-1 and 38-2 for the legs 34-1 and 34-2 (not shown) for the common power configuration and the second leg placement positions 40-1 and 40-2 for the legs 34-1 and 34-2 for the separate power configuration. More specifically, the pads 60-1 and 60-2 include areas at which the legs 34-1 and 34-2 are to be connected for the first leg placement positions 38-1 and 38-2 and the second leg placement positions 40-1 and 40-2. The bottom header 30-1 also includes the positive and negative contact pads 52 and 54 for powering the lower stage of thermoelectric devices 36 in the separate power configuration and both the lower and upper stages of thermoelectric devices 36 and 46 (in series) in the common power configuration.

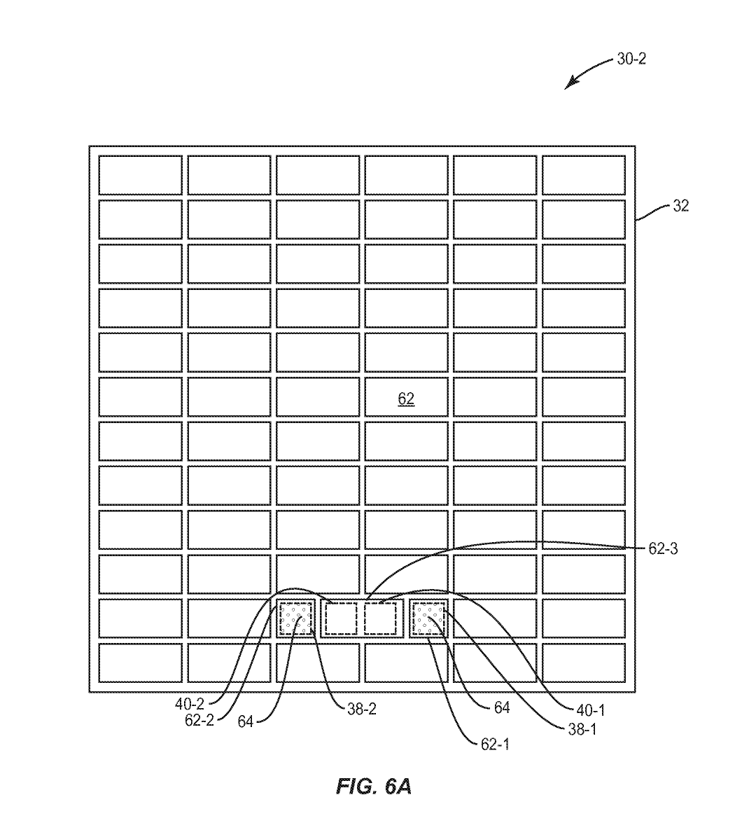

FIG. 6A illustrates the bottom surface 32 of the intermediate header 30-2 of the cascade TEM 28, and FIG. 6B illustrates the upper surface 42 of the intermediate header 30-2 of the cascade TEM 28 according to some embodiments of the present disclosure. As shown, the bottom surface 32 of the intermediate header 30-2 includes multiple pads 62 that, together with the corresponding pads 60 of the bottom header 30-1, electrically connect the legs 34 (not shown) to form the lower stage of thermoelectric devices 36 (not shown) that are electrically connected to one another in series. In particular, the bottom ends of the legs 34 are electrically connected to corresponding leg placement positions on the pads 60 of the bottom header 30-1, whereas the top ends of the legs 34 are electrically connected to corresponding leg placement positions on the respective pads 62 on the bottom surface 32 of the intermediate header 30-2.

Further, in this example, three of the pads 62, which are referred to as pads 62-1, 62-2, and 62-3, define both the first leg placement positions 38-1 and 38-2 for the legs 34-1 and 34-2 (not shown) for the common power configuration and the second leg placement positions 40-1 and 40-2 for the legs 34-1 and 34-2 for the separate power configuration, with respect to the bottom surface 32 of the intermediate header 30-2. Specifically, the pads 62-1 and 62-2 define the first leg placement positions 38-1 and 38-2 for the legs 34-1 and 34-2 (specifically for the top ends of the legs 34-1 and 34-2, not shown) for the common power configuration. As illustrated, the first leg placement positions 38-1 and 38-2 are electrically coupled to the respective first leg placement positions 48-1 and 48-2 on the upper surface 42 of the intermediate header 30-2 by vias 64 through the intermediate header 30-2. The pad 62-3 defines the second leg placement positions 40-1 and 40-2 for the legs 34-1 and 34-2 (not shown) for the separate power configuration. More specifically, the pad 62-3 includes areas at which the legs 34-1 and 34-2 are to be connected for the second leg placement positions 40-1 and 40-2. As illustrated, there are no vias 64 in the second leg placement positions 40-1 and 40-2 and, as such, the lower and upper stages of thermoelectric devices 36 and 46 are electrically decoupled when the legs 34-1 and 34-2 are positioned in the second leg placement positions 40-1 and 40-2.

As illustrated in FIG. 6B, the upper surface 42 of the intermediate header 30-2 also includes multiple pads 66 that, together with corresponding pads of the top header 30-3, electrically connect the legs 44 (not shown) to form the upper stage of thermoelectric devices 46 that are electrically connected to one another in series. In particular, the bottom ends of the legs 44 are electrically connected to corresponding leg placement positions on the pads 66 on the upper surface 42 of the intermediate header 30-2, whereas top ends of the legs 44 are electrically connected to corresponding leg placement positions on the respective pads on the top header 30-3 (not shown).

Further, in this example, two of the pads 66, which are referenced as pads 66-1 and 66-2, define the first leg placement positions 48-1 and 48-2 for the legs 44-1 and 44-2 (not shown) for the common power configuration. In this example, the second leg placement positions 50-1 and 50-2 for the legs 44-1 and 44-2 for the separate power configurations are provided by the positive and negative contact pads 56 and 58, respectively. Specifically, the pads 66-1 and 66-2 define the first leg placement positions 48-1 and 48-2 for the legs 44-1 and 44-2 (specifically for the bottom ends of the legs 44-1 and 44-2 (not shown)) for the common power configuration. As illustrated, the first leg placement positions 48-1 and 48-2 are electrically coupled to the respective first leg placement positions 38-1 and 38-2 (not shown) on the bottom surface 32 (not shown) of the intermediate header 30-2 by the vias 64 through the intermediate header 30-2. The positive and negative contact pads 56 and 58 define the second leg placement positions 50-1 and 50-2 for the legs 44-1 and 44-2 (specifically for the bottom ends of the legs 44-1 and 44-2) for the separate power configuration. More specifically, the positive and negative contact pads 56 and 58 include areas at which the legs 44-1 and 44-2 are to be connected for the second leg placement positions 50-1 and 50-2. As illustrated, there are no vias 64 through the intermediate header 30-2 at the second leg placement positions 50-1 and 50-2 and, as such, the lower and upper stages of thermoelectric devices 36 and 46 are electrically decoupled when the legs 44-1 and 44-2 are positioned in the second leg placement positions 50-1 and 50-2.

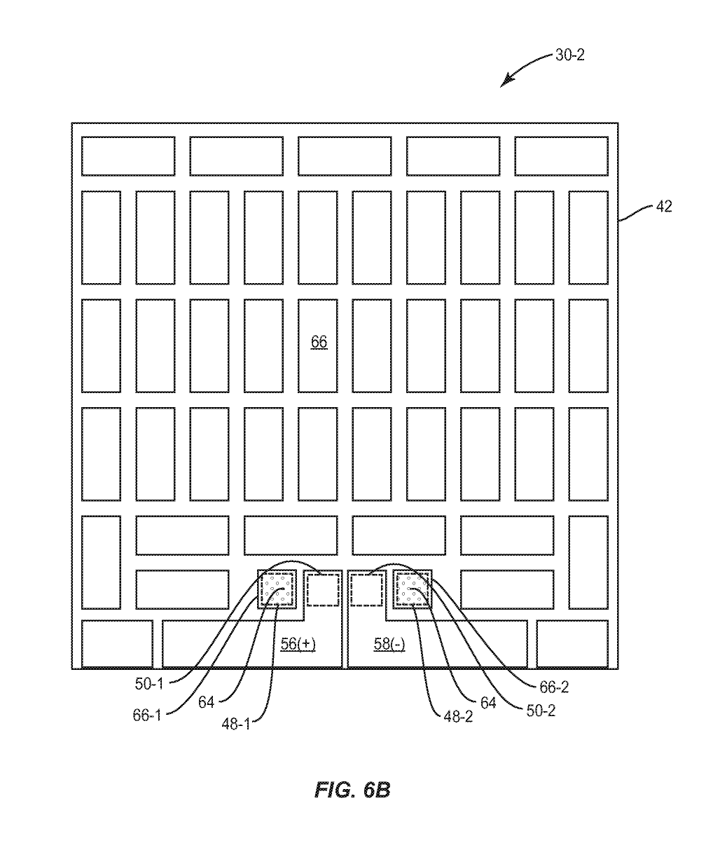

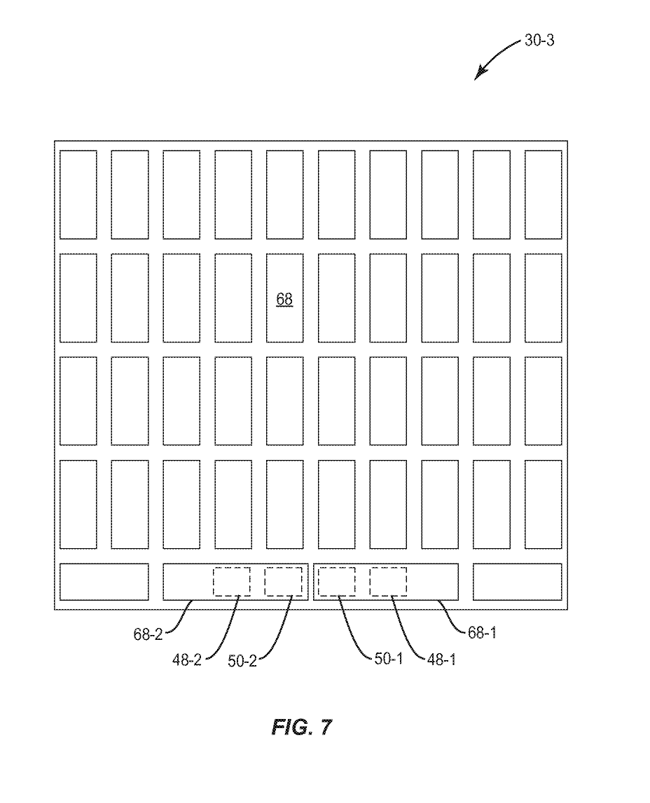

FIG. 7 illustrates the top header 30-3 of the cascade TEM 28 of FIGS. 4A and 4B according to some embodiments of the present disclosure. As shown, the top header 30-3 includes multiple pads 68 that, together with the corresponding pads 66 (not shown) on the upper surface 42 (not shown) of the intermediate header 30-2 (not shown), electrically connect the legs 44 (not shown) to form the upper stage of thermoelectric devices 46 that are electrically connected to one another in series. In particular, the top ends of the legs 44 are electrically connected to corresponding leg placement positions on the pads 68, whereas the bottom ends of the legs 44 are electrically connected to corresponding leg placement positions on the respective pads 66 on the upper surface 42 of the intermediate header 30-2. Further, in this example, two of the pads 68, which are referred to as pads 68-1 and 68-2, are elongated pads that define both the first leg placement positions 48-1 and 48-2 for the legs 44-1 and 44-2 (not shown) for the common power configuration and the second leg placement positions 50-1 and 50-2 for the legs 44-1 and 44-2 for the separate power configuration. More specifically, the pads 68-1 and 68-2 include areas at which the legs 44-1 and 44-2 are to be connected for both the first leg placement positions 48-1 and 48-2 and the second leg placement positions 50-1 and 50-2.

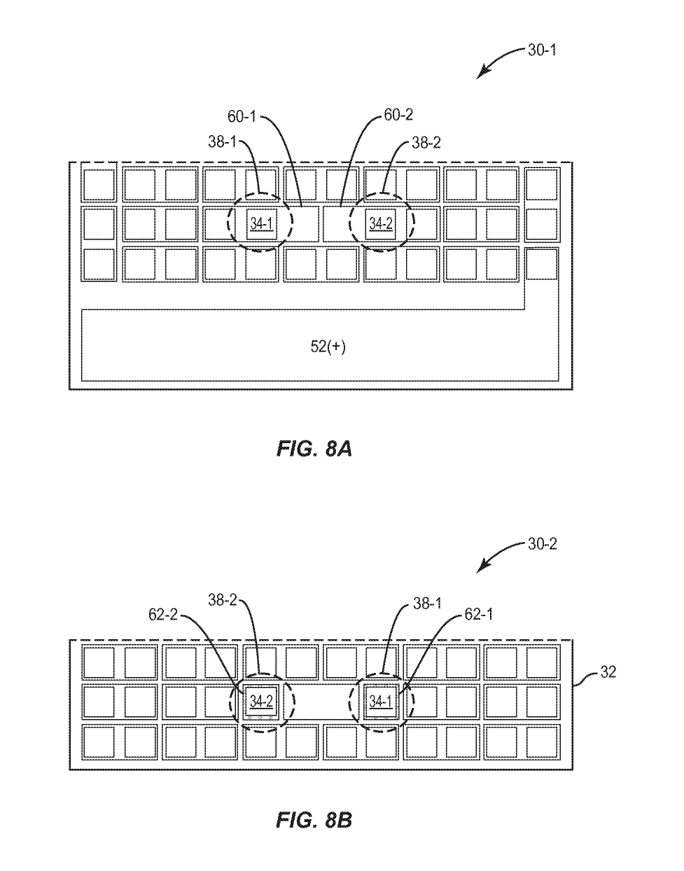

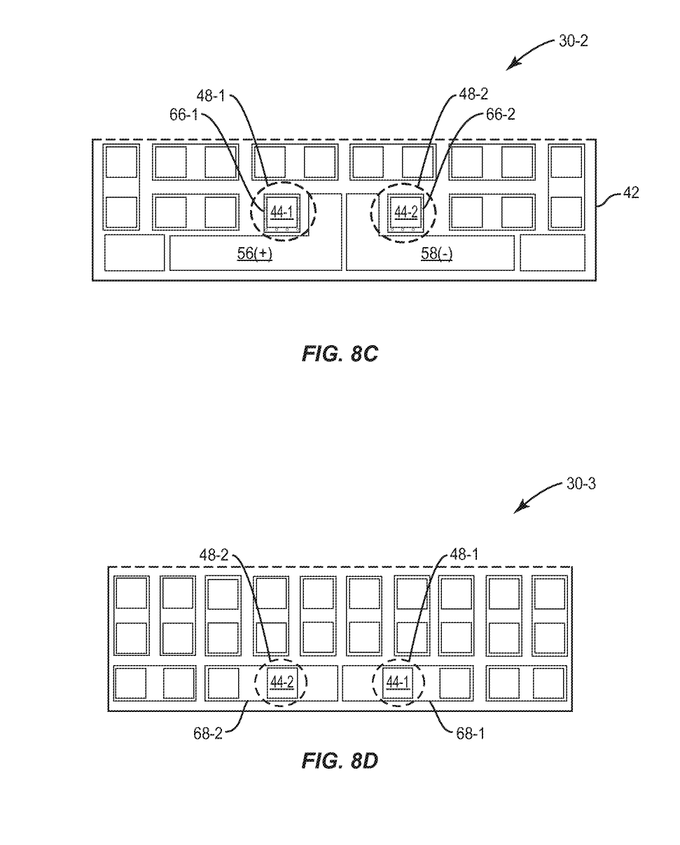

FIGS. 8A through 8D illustrate portions of the bottom header 30-1, the bottom surface 32 of the intermediate header 30-2, the upper surface 42 of the intermediate header 30-2, and the top header 30-3, respectively, including the subset of legs 34 and 44 positioned in the first leg placement positions 38 and 48 to enable common power operations according to some embodiments of the present disclosure. As shown in FIG. 8A, with respect to the bottom header 30-1, the bottom ends of the legs 34-1 and 34-2 are electrically (and thermally) connected to the pads 60-1 and 60-2 of the bottom header 30-1 at the first leg placement positions 38-1 and 38-2, respectively. As shown in FIG. 8B, with respect to the bottom surface 32 of the intermediate header 30-2, the upper ends of the legs 34-1 and 34-2 of the lower stage of thermoelectric devices 36 are electrically (and thermally) connected to the pads 62-1 and 62-2 of the bottom surface 32 of the intermediate header 30-2 at the first leg placement positions 38-1 and 38-2, respectively.

As shown in FIG. 8C, with respect to the upper surface 42 of the intermediate header 30-2, the bottom ends of the legs 44-1 and 44-2 of the upper stage of thermoelectric devices 46 are electrically (and thermally) connected to the pads 66-1 and 66-2 of the upper surface 42 of the intermediate header 30-2 at the first leg placement positions 48-1 and 48-2, respectively. As shown in FIG. 8D, with respect to the top header 30-3, the top ends of the legs 44-1 and 44-2 of the upper stage of thermoelectric devices 46 are electrically (and thermally) connected to the pads 68-1 and 68-2 of the top header 30-3 at the first leg placement positions 48-1 and 48-2, respectively. When the legs 34-1 and 34-2 (not shown) of the lower stage of thermoelectric devices 36 and the legs 44-1 and 44-2 of the upper stage of thermoelectric devices 46 are placed in the first leg placement positions 38-1, 38-2, 48-1, and 48-2, respectively, the lower stage of thermoelectric devices 36 are electrically connected in series with the upper stage of thermoelectric devices 46 by the vias 64 (not shown) through the intermediate header 30-2. This, in turn, enables common power operation of the lower and upper stages of thermoelectric devise 36 and 46 of the cascade TEM 28.

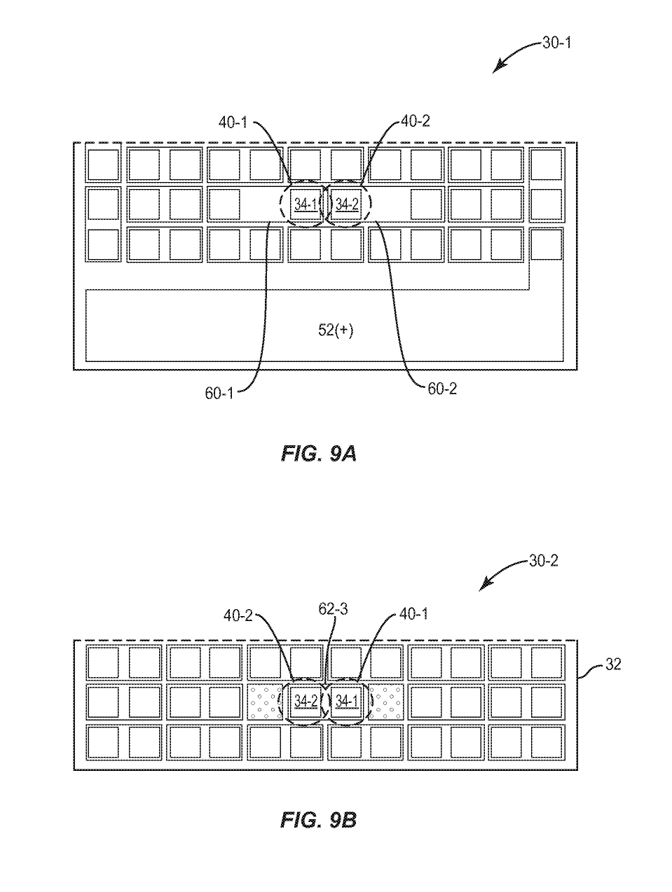

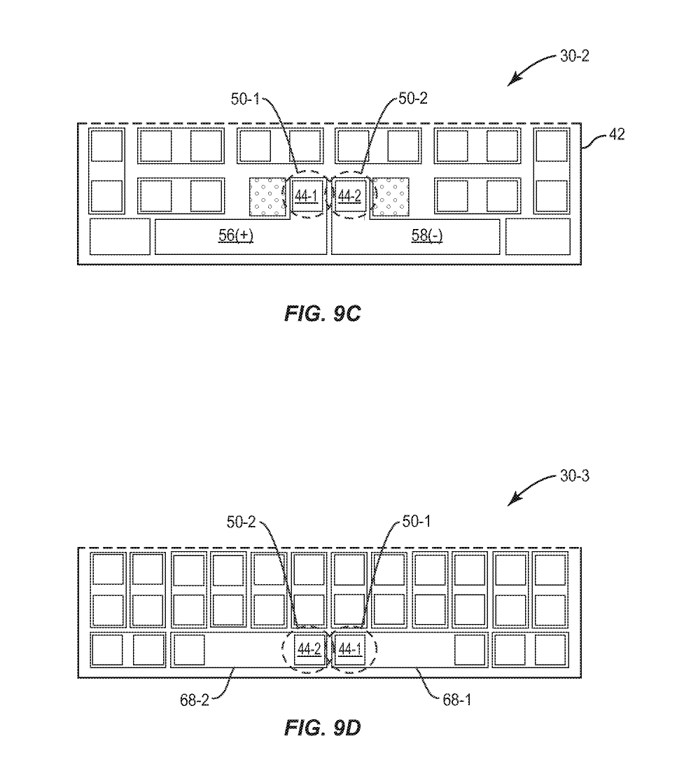

FIGS. 9A through 9D illustrate portions of the bottom header 30-1, the bottom surface 32 of the intermediate header 30-2, the upper surface 42 of the intermediate header 30-2, and the top header 30-3, respectively, including the subset of legs 34 and 44 positioned in the second leg placement positions 40 and 50 to enable separate power operations according to some embodiments of the present disclosure. As shown in FIG. 9A, with respect to the bottom header 30-1, the bottom ends of the legs 34-1 and 34-2 are electrically (and thermally) connected to the pads 60-1 and 60-2 of the bottom header 30-1 at the second leg placement positions 40-1 and 40-2, respectively. As shown in FIG. 9B, with respect to the bottom surface 32 of the intermediate header 30-2, the upper ends of the legs 34-1 and 34-2 of the lower stage of thermoelectric devices 36 are electrically (and thermally) connected to the pad 62-3 of the bottom surface 32 of the intermediate header 30-2 at the second leg placement positions 40-1 and 40-2, respectively.

As shown in FIG. 9C, with respect to the upper surface 42 of the intermediate header 30-2, the bottom ends of the legs 44-1 and 44-2 of the upper stage of thermoelectric devices 46 are electrically (and thermally) connected to the positive and negative contact pads 56 and 58 of the upper surface 42 of the intermediate header 30-2 at the second leg placement positions 50-1 and 50-2, respectively. As shown in FIG. 9D, with respect to the top header 30-3, the top ends of the legs 44-1 and 44-2 of the upper stage of thermoelectric devices 46 are electrically (and thermally) connected to the pads 68-1 and 68-2 of the top header 30-3 at the second leg placement positions 50-1 and 50-2, respectively. When the legs 34-1 and 34-2 (not shown) of the lower stage of thermoelectric devices 36 and the legs 44-1 and 44-2 of the upper stage of thermoelectric devices 46 are placed in the second leg placement positions 40-1, 40-2, 50-1, and 50-2, respectively, the lower stage of thermoelectric devices 36 (not shown) are electrically decoupled from the upper stage of thermoelectric devices 46. This, in turn, enables separate power operation of the lower and upper stages of thermoelectric devices 36 and 46 of the cascade TEM 28.

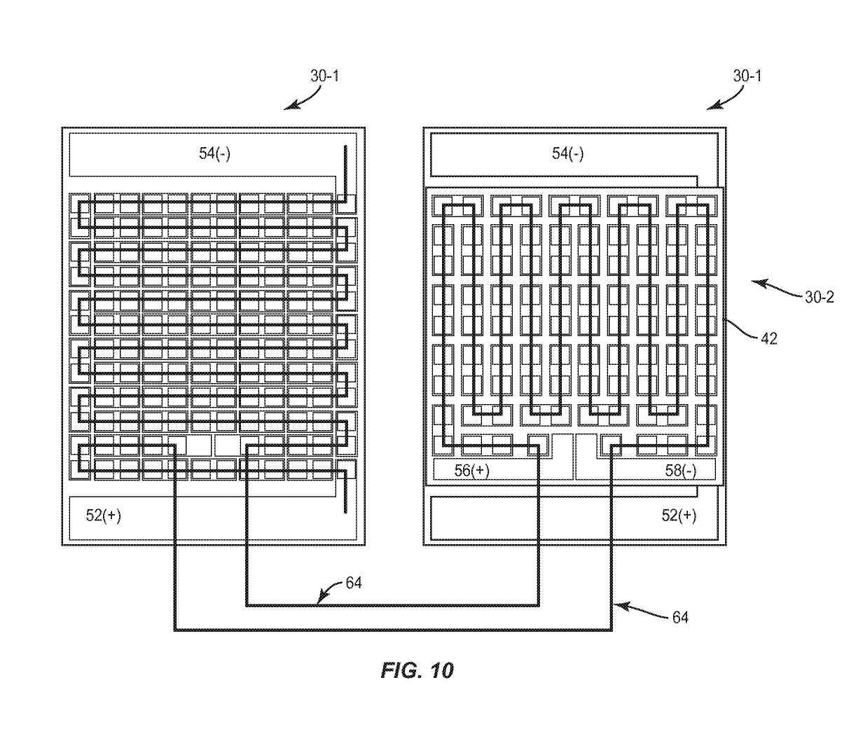

FIG. 10 illustrates the lower and upper stages of thermoelectric devices 36 and 46, respectively, electrically interconnected in series by the vias 64 (which in FIG. 10 are represented by corresponding lines) through the intermediate header 30-2 when the subsets of the legs 34 and 44 (not shown) are positioned on the respective first leg placement positions 38 and 48 (not shown) for the common power configuration according to some embodiments of the present disclosure. As shown, in this example, the positive and negative contact pads 52 and 54 of the bottom header 30-1 are used to electrically connect a common power source to the lower and upper stages of thermoelectric devices 36 and 46 of the cascade TEM 28 in series for the common power configuration. Notably, each of the lower and upper stages shown in FIG. 10 has two leg positions that are unpopulated to allow for both the common power configuration (series arrangement) or the separate power configuration (separate arrangement) on the same header design.

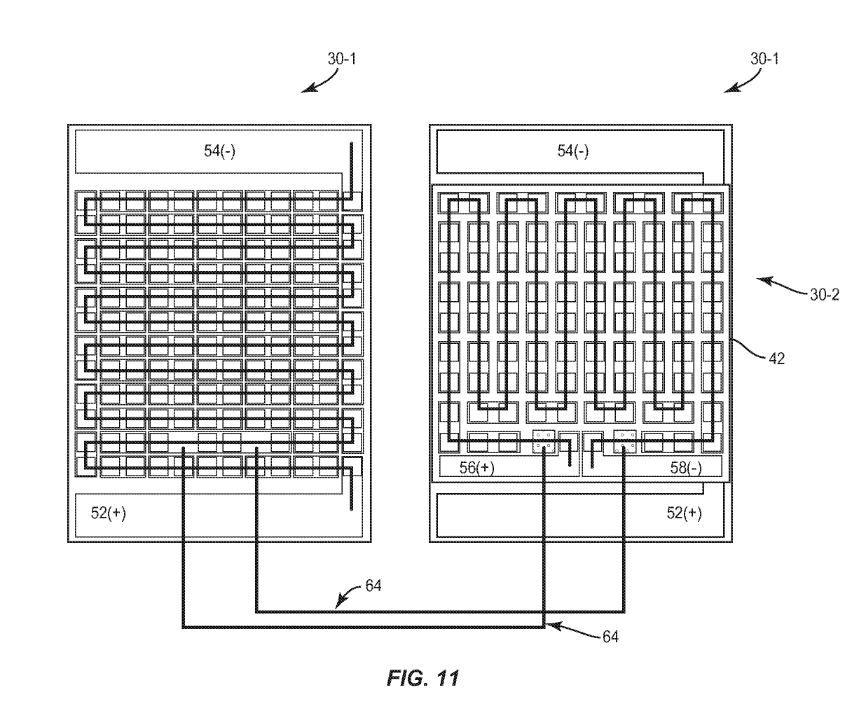

FIG. 11 illustrates the lower and upper stages of thermoelectric devices 36 and 46, respectively, electrically decoupled within the cascade TEM 28 when the subsets of the legs 34 and 44 (not shown) are positioned on the respective second leg placement positions 40 and 50 (not shown) for the separate power configuration according to some embodiments of the present disclosure. The vias 64 (not shown) do not interconnect with the legs 34 and 44 when positioned at the respective second leg placement positions 40 and 50 and, as such, the lower stage of thermoelectric devices 36 are electrically decoupled from the upper stage of thermoelectric devices 46. Accordingly, the positive and negative contact pads 52 and 54 of the bottom header 30-1 are used for powering the lower stage of thermoelectric devices 36 alone. In addition, the positive and negative contact pads 56 and 58 of the intermediate header 30-2 are used for powering the upper stage of thermoelectric devices 46 separate from powering the lower stage of thermoelectric devices 36.

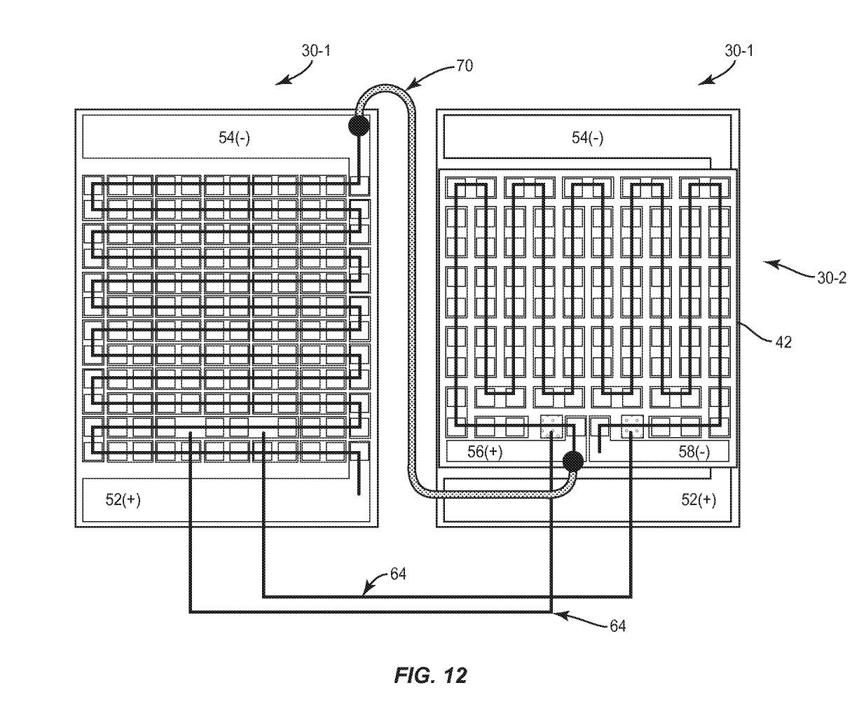

In some embodiments, when the cascade TEM 28 is configured in the separate power configuration, the operational mode of the cascade TEM 28 can be adapted with one or more external electrical connectors. More specifically, one or more electrical connectors may be utilized to interconnect (potentially selectively), e.g., the positive and negative contact pads 54 and 56 of the cascade TEM 28 to either operate the cascade TEM 28 in a separate power mode (e.g., when the positive and negative contact pads 54 and 56 are not electrically connected) or a common power configuration (e.g., when the positive and negative contact pads 54 and 56 are electrically connected). For example, FIG. 12 illustrates an external electrical connector 70 utilized to electrically connect the lower and upper stages of thermoelectric devices 36 and 46 in series when the cascade TEC 28 is itself configured in the separate power configuration as shown in FIG. 11 according to some embodiments of the present disclosure. As shown, the external electrical connector 70 is physically external to the cascade TEM 28. In this example, the external electrical connector 70 electrically couples the negative contact pad 54 of the bottom header 30-1 to the positive contact pad 56 of the intermediate header 30-2 to enable the lower and upper stages of the cascade TEM 28 to be electrically coupled in series through the external electrical connector 70.

In some embodiments, the external electrical connector 70 may provide a permanent (e.g., static) electrical connection between the lower and upper stages of thermoelectric devices 36 and 46 of the cascade TEM 28. For example, the external electrical connector 70 may comprise a wire or an equivalent thereof that statically connects the negative contact pad 54 of the bottom header 30-1 to the positive contact pad 56 of the intermediate header 30-2. In some embodiments, the external electrical connector 70 may provide a reconfigurable (e.g., dynamic) electrical connection between the lower and upper stages of thermoelectric devices 36 and 46 of the cascade TEM 28. For example, the external electrical connector 70 may comprise a wire(s) coupled to a switch that can be used to selectively couple and decouple the negative contact pad 54 of the bottom header 30-1 to the positive contact pad 56 of the intermediate header 30-2.

As such, the cascade TEM 22 in the separate power configuration can be adapted in an “external common power mode” to receive power from a common power source (e.g., from a common current source) to power both stages of the cascade TEM 28. For example, a common current source may be coupled to the positive contact pad 52 of the bottom header 30-1 and the negative contact pad 58 of the intermediate header 30-2 to power both stages of the cascade TEM 28. Thus, although each stage can be configured to be powered separately, the external electrical connector 70 can be used to electrically couple the lower and upper stages of thermoelectric devices 36 and 46 in series such that the cascade TEM 28 is configured to receive power from a single source.

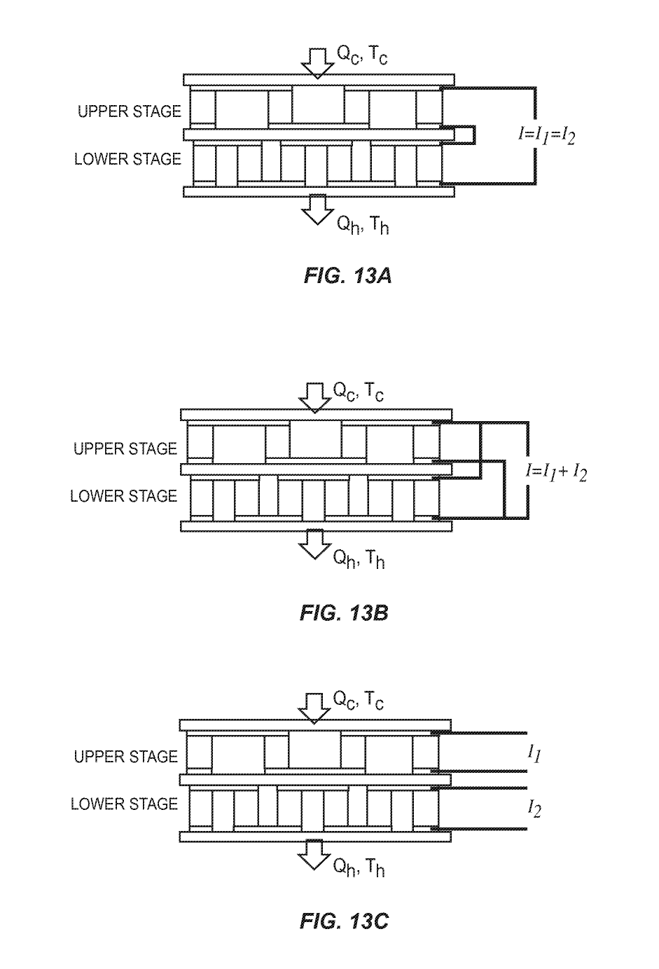

In some embodiments, when the cascade TEM 28 is configured in the separate power configuration, the cascade TEM 28 can be adapted externally to operate in different modes. FIGS. 13A through 13C illustrate different modes of operation for the cascade TEM 28 when the cascade TEM 28 is configured in the separate power configuration according to some embodiments of the present disclosure. For example, a control system external to the cascade TEM 28 may selectively control a mode of operation of the cascade TEM 28 when the cascade TEM 28 is configured (internally by leg placement) in the separate power configuration. Unlike the common and separate power configurations determined by the placement of the subset of legs 34 and 44 internal to the cascade TEM 28, the modes of operation for the separate power configuration are determined by components and controls that are at least partly physically external to the cascade TEM 28. The modes of operation may include the external common power mode described above, a single-power separate power mode where the cascade TEM 28 is powered by a single source, or a multi-power separate power mode where the lower and upper stages of thermoelectric devices of the cascade TEM 28 are powered by distinct sources.

FIG. 13A illustrates the external common power mode of operation of FIG. 12, whereby the external electrical connector(s) 70 (not shown) is used to electrically couple the lower and upper stages of thermoelectric devices in series. As such, the cascade TEM 28 is enabled to receive power from a single power source (e.g., current or voltage sources) coupled to the other contact pads of the bottom header 30-1 (not shown) and the intermediate header 30-2 (not shown). Accordingly, the external common power mode provides a serial connection where current from the same source flows through both stages. Since the stages are operated together, this simplifies control of the cascade TEM 28 because there is only one current input.

FIGS. 13B and 13C show two separate power modes in which the stages of the cascade TEM 28 are powered by the same source (i.e., connected to the same source in parallel) or powered by distinct sources, respectively. In particular, FIG. 13B shows a separate power mode wherein the lower and upper stages of thermoelectric devices are connected in parallel to a single current source (i.e., there is a parallel connection to the single current source). Thus, if the single current source provides a current I, then a current I₁ will flow through the lower stage of thermoelectric devices and a current I₂ will flow through the upper stage of thermoelectric devices, where I₁+I₂=I. In contrast, FIG. 13C shows a separate power mode of operation wherein the lower and upper stages of thermoelectric devices are powered by distinct power sources (e.g., current source). As such, the lower stage of thermoelectric devices is powered independently of the upper stage of thermoelectric devices and the upper stage of thermoelectric devices is powered independently of the lower stage of thermoelectric devices. Accordingly, the mode of operation illustrated in FIG. 13C provides true (i.e., actual) separate connections for independent control of the individual stages. Since the stages operate independently, this mode provides more flexibility and higher performance over the serial and parallel connections discussed above.

Referring back to the embodiment shown in FIG. 12, the separate power mode of operation of the cascade TEM 28 in the separate power configuration can be static or dynamic by selectively activating or deactivating one or more external electrical connectors (e.g., the external electrical connector 70). As such, the cascade TEM 28 in the separate power configuration provides the added benefits that each stage can be operated independently at specific operating points to optimize performance. Moreover, in some embodiments, when the cascade TEM 28 is configured in the separate power configuration, the external electrical connector(s) 70 can be used to externally switch the cascade TEM 28 from the separate power configuration to an (external) common power mode. For example, in some embodiments, a control system that is connected to the cascade TEM 28 may include a controller to control power control and switching circuitry used to set different modes of operation for the cascade TEM 28. As a result, these embodiments overcome the problems with existing systems by providing a cascade TEM in a multi-power system that is flexible for use with different applications. As such, the control system connected to the cascade TEM 28 may be operable to select and switch between any of the modes of operation discussed above.

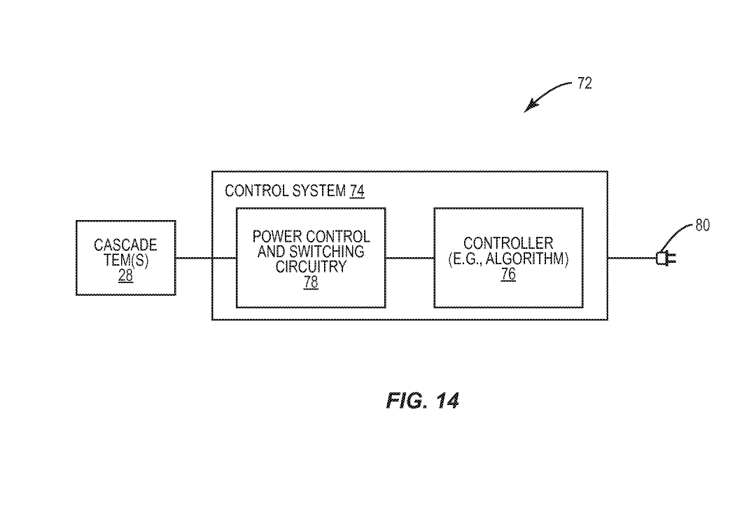

For example, FIG. 14 is a block diagram of a thermoelectric system 72 that includes a control system 74 and one or more of the cascade TEMs 28 in which a controller (e.g., an algorithm) 76 and power control and switching circuitry 78 of the control system 74 selectively operates the cascade TEM(s) 28 in accordance with different modes of operation according to some embodiments of the present disclosure. Specifically, the control system 74 operates to supply power to the cascade TEM(s) 28 from a source 80 that may be external to the thermoelectric system 74 (e.g., an Alternating Current (AC) outlet connected to the power grid). The controller 76 operates to select a mode of operation for the cascade TEM(s) 28 in accordance with any of the modes of operation discussed above. The controller 76 controls the power control and switching circuitry 78 to configure the cascade TEM(s) 28 to implement the selected mode of operation. The power control and switching circuitry 78 may include, for example, one or more current sources that may, for example, provide variable Direct Current (DC) under the control of the controller 76. The power control and switching circuitry 78 also includes switching circuitry that selectively activates or deactivates the external electrical connector 70 for connecting the stages of the cascade TEC 28 in series under the control of the controller 76.

In some embodiments, the controller 76 may include one or more processors (e.g., one or more microprocessors, one or more Field Programmable Gate Arrays (FPGAs), one or more Application Specific Integrated Circuits (ASICs), control logic, or the like), memory, and one or more Input/Output (I/O) components (e.g., an interface(s) for receiving a temperature reading(s) from a temperature sensor(s)). In some embodiments, the functionality of the controller 76 described herein is implemented in software and stored in the memory for execution by the one or more processors of the controller 76.

In some embodiments, a computer program including instructions which, when executed by at least one processor, causes the at least one processor to carry out the functionality of the controller 76 according to any one of the embodiments described herein is provided. In some embodiments, a carrier containing the aforementioned computer program product is provided. The carrier is one of an electronic signal, an optical signal, a radio signal, or a computer readable storage medium (e.g., a non-transitory computer readable medium such as the memory of the controller 76).

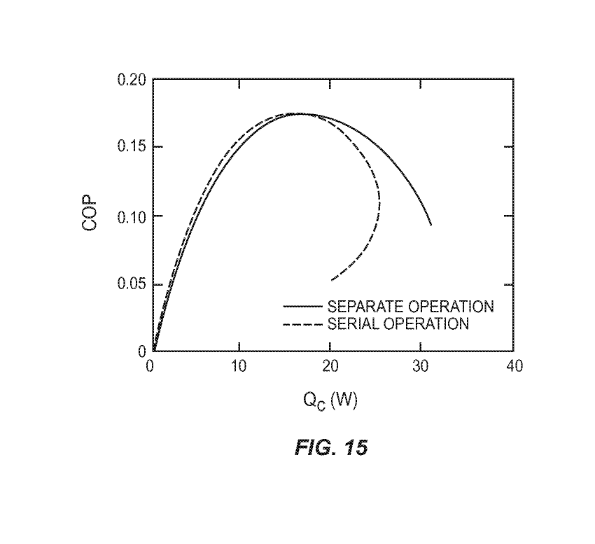

FIG. 15 is a graph illustrating Coefficient of Performance (COP) curves for the cascade TEM 28 that utilizes a common operation (e.g., serial operation) and/or a separate operation according to some embodiments of the present disclosure. A COP of a cascade TEM operating as a Thermoelectric Cooler (TEC) module, for example, is a measure of the efficiency of the cascade TEM, and is defined as: COP=Q_{C}/Pᵢₙ, where Q_{C} is heat pumped by the cascade TEM and Pᵢₙ is the input power to the cascade TEM. FIG. 15 includes COP vs. Q_{C} curves for the separate power configuration (when also being controlled externally to achieve the separate power mode of operation) of the cascade TEM 28 (solid line) and the (external or internal) common power configuration of the cascade TEM 28 (dashed line).

In FIG. 15, Q_{C} is the amount of heat pumped by the cascade TEM 28. As illustrated, for the common power configuration, the COP, and thus efficiency, of the cascade TEM 28 decreases for high values of Q_{C}. Further, at some point, if a current (or more generally power) supplied to the cascade TEM 28 is further increased, both efficiency and the amount of heat pumped will decrease. Conversely, for the separate power configuration, both efficiency and the amount of heat pumped are improved. As such, the separate power mode of operation can provide higher COP over a wide range of heat pumping capacities. However, advantages of the serial operation include easier implementation in practice because of simpler controls, power electronics, firmware, and the like. As such, separate and serial operations have advantages and drawbacks that may be desirable or suitable for different applications.

The dimensions and numbers of headers, legs, subsets of legs, stages, contacts, and other components are not limited to the embodiments shown in FIGS. 4A and 4B. In some embodiments, the cascade TEM 28 may include any number of stages having the corresponding number of headers for flexibility to adapt to a wide range of applications. Further, while each subset of the legs 34, 44 illustrated in FIGS. 4A and 4B includes only a pair of legs, each subset may include more than two legs.

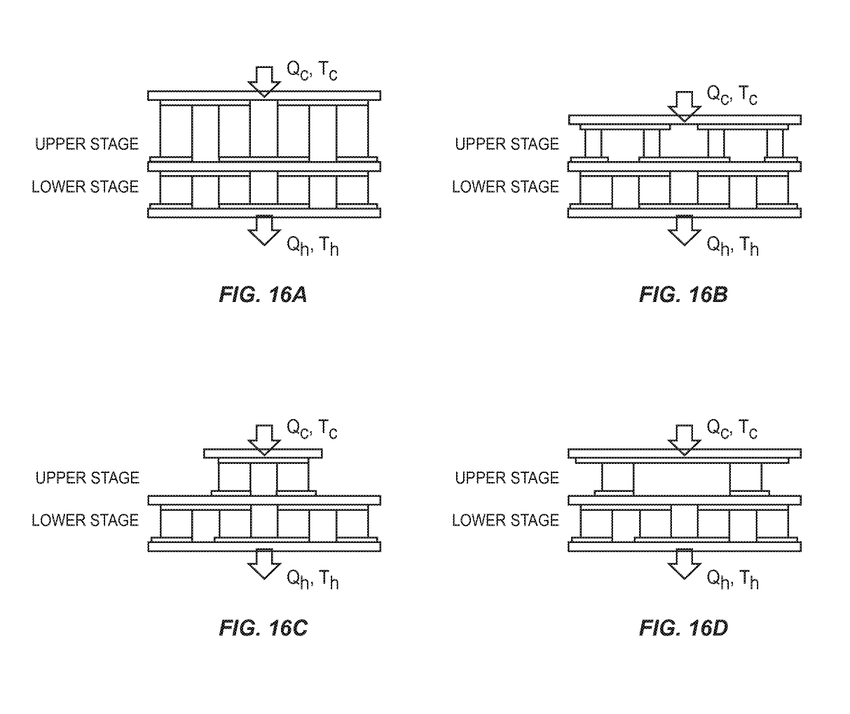

As some examples, FIGS. 16A through 16D illustrate various constructions of cascade TEMs utilizing different structures according to some embodiments of the present disclosure. Each construction of the cascade TEM includes a first stage and a second stage. Arrows show the direction of the heat pumped (Q_{c}) from a cold side at a temperature (T_{c}), and heat rejected (Qₕ) at a hot side temperature (Tₕ) of the cascade TEMs.

In particular, FIGS. 16A and 16B show cascade TEM constructions with a number of legs in the upper stage of thermoelectric devices and a number of legs in the lower stage of thermoelectric devices. The legs in the upper stage of thermoelectric devices have equivalent dimensions with respect to each other. The legs in the lower stage of thermoelectric devices also have equivalent dimensions with respect to each other. However, the dimensions of the legs in the upper stage of thermoelectric devices are different from the dimensions of the legs in the lower stage of thermoelectric devices.

Specifically, FIG. 16A shows that the legs of the upper stage of thermoelectric devices have thicknesses different than the thicknesses of the lower stage of thermoelectric devices. FIG. 16B, in contrast, shows that the legs of the upper stage of thermoelectric devices have leg widths, or potentially cross-sectional areas, different than that of the lower stage of thermoelectric devices leg widths.

FIGS. 16C and 16D show cascade TEM constructions with a total number of legs in the upper stage of thermoelectric devices that is different than the total number of legs in the lower stage of thermoelectric devices. As shown, the upper stages of thermoelectric devices have fewer legs than the lower stages of thermoelectric devices. In particular, FIG. 16C shows a cascade TEM that forms a pyramidal shaped structure by maintaining uniform spacing between legs in both stages and utilizing a top header that has a smaller area than the intermediate and bottom headers. As such, the cascade TEM of FIG. 16C has a pyramidal shape with the same size legs.

FIG. 16D shows a cascade TEM construction that also has fewer legs in the upper stage of thermoelectric devices compared to the lower stage of thermoelectric devices. The upper and lower stages of thermoelectric devices also include legs of the same size. However, in contrast to FIG. 16C, the legs in the upper stage of thermoelectric devices of FIG. 16D are spaced apart further from each other compared to the legs in the lower stage of thermoelectric devices. As such, this cascade TEM construction uses the same size headers.

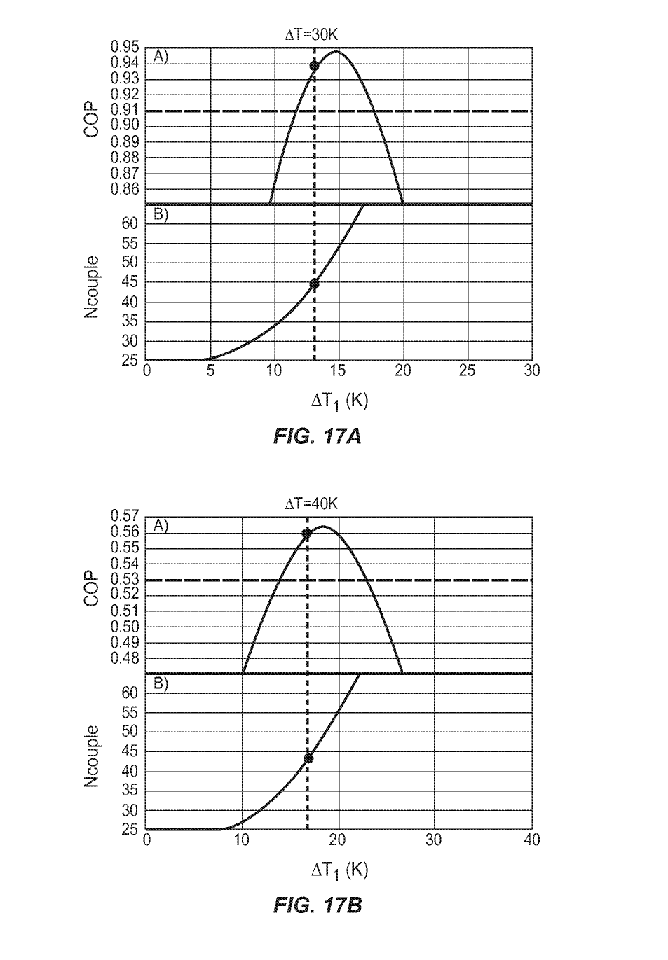

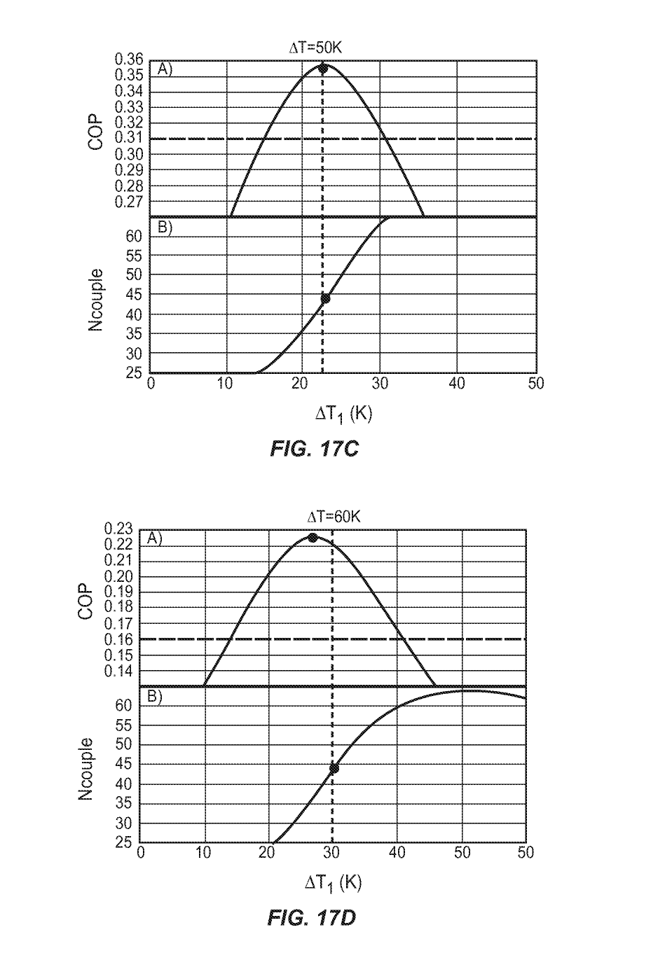

FIGS. 17A through 17D are graphs illustrating the optimization of a number of legs for the upper stage of the cascade TEM 28 to obtain a maximum increase in COP depending on a ΔT according to some embodiments of the present disclosure. In particular, FIGS. 17A through 17D show optimization of the number of legs for the upper stage of the cascade TEM 28 to obtain a maximum increase in COP at ΔT=30 Kelvin (K), 40 K, 50 K, and 60 K. In particular, FIG. 17A shows an optimization of the number of legs for the upper stage of the cascade TEM 28 to maximize the increase in COP at ΔT=30 K. FIG. 17B shows an optimization of the number of legs for the upper stage of the cascade TEM 28 to maximize the increase in COP at ΔT=40 K. FIG. 17C shows an optimization of the number of legs for the upper stage of the cascade TEM 28 to maximize the increase in COP at ΔT=50 K. FIG. 17D shows an optimization of the number of legs for the upper stage of the cascade TEM 28 to maximize the increase in COP at ΔT=60 K. As such, FIGS. 17A through 17D illustrate one example of how the number of legs for the upper stage of the cascade TEM 28 may vary depending on the particular implementation (e.g., depending on the desired ΔT).

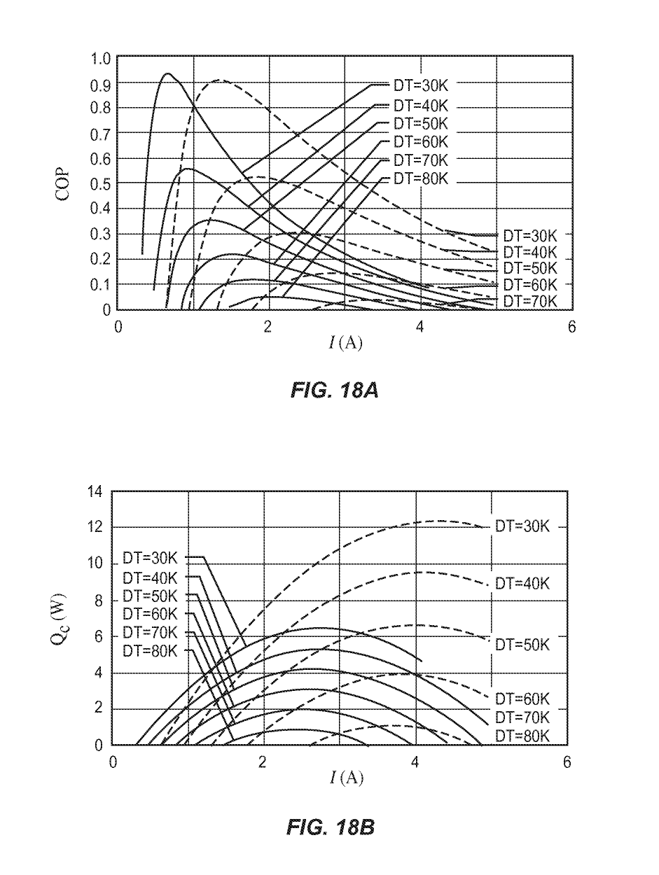

FIGS. 18A and 18B are graphs illustrating performance curves for serial connectivity of a cascade TEM according to some embodiments of the present disclosure. Specifically, FIGS. 18A and 18B illustrate the performance of a single stage TEM (dashed lines) compared to the performance of a cascade TEM (solid lines). As shown, the maximum current (Iₘₐₓ) is shifted to a lower current of 3 Amperes (A) instead of 4 A. Heat pumping (Q_{c}) is about half of the single TEM for a lower ΔT. On the other hand, heat pumping of the cascade TEM is greater for larger ΔTs. Thus, the performance of the cascade TEM under operation is better than the performance of the single stage TEM.

Embodiments of the disclosed cascade TEM improve COP by 1-50% over a single TEM architecture. Predicted COP increases include 4% for ΔT=30 K, 20% for ΔT=50 K, and 50% for ΔT=60 K. In some embodiments, the form factor of the cascade TEM may be similar to the form factor of a single TEM. The leg size may be the same or similar to the legs used in a single TEM. Further, both the serial (i.e., common) and separate operations are possible with controls that enable either operation. Although the cascade TEM discussed above includes headers with a rectangular layout of pads, except for the contact pad leg placement positions, the disclosure is not limited thereto.

The following tables provide numerical values for features of some embodiments of the present disclosure to illustrate specific implementations. However, the disclosure is not limited thereto. TABLE 1 shows the expected performance improvements of the disclosed cascade TEM over a single TEM, according to some embodiments of the present disclosure.

TABLE 1

| | SINGLE STAGE | TWO STAGE | |
|---|---|---|---|
| ΔT(K) | TEM | TEM | % IMPROVEMENT |
| 30 | 0.90 | 0.93 | 4% |
| 40 | 0.53 | 0.56 | 6% |
| 50 | 0.29 | 0.35 | 21% |
| 60 | 0.15 | 0.22 | 47% |
| 70 | 0.03 | 0.12 | 300% |
| 80 | | 0.07 | |

TABLE 2 shows examples of leak-back in the cascade TEM 28 according to some embodiments of the present disclosure. As shown, the loss in the first stage is not significantly greater than the loss in the second stage.

TABLE 2

| | STAGE 2 | STAGE1 |
|---|---|---|
| A_{BiTe}(mm²) | 183 | 183 |
| A_{Headers}(mm²) | 92 | 58 |
| Fill fraction (%) | 50% | 36% |
| R_{th, leakback}(K/W) | 390 | 350 |
| Total loss in Qc at DT = 40(W) | 0.1 | 0.12 |

Those skilled in the art will recognize improvements and modifications to the preferred embodiments of the present disclosure. All such improvements and modifications are considered within the scope of the concepts disclosed herein and the claims that follow.

What is claimed is:

1. A cascade thermoelectric module, comprising:
a plurality of headers comprising a first header, a second header, and a third header,
the first header and a first surface of the second header configured to electrically connect a first plurality of legs to form a first stage of thermoelectric devices electrically connected in series, the first header and the first surface of the second header defining a first set of leg placement positions for a subset of the first plurality of legs and a second set of leg placement positions for the subset of the first plurality of legs;
a second surface of the second header and the third header configured to electrically connect a second plurality of legs to form a second stage of thermoelectric devices electrically connected in series, the second surface of the second header and the third header defining a first set of leg placement positions for a subset of the second plurality of legs and a second set of leg placement positions for the subset of the second plurality of legs; and
the second header being further configured such that:
the first and second stages of thermoelectric devices are electrically coupled in series when the subsets of the first and second pluralities of legs are positioned in the respective first sets of leg placement positions; and
the first and second stages of thermoelectric devices are electrically decoupled within the cascade thermoelectric module when the subsets of the first and second pluralities of legs are positioned in the respective second sets of leg placement positions.

2. The cascade thermoelectric module of claim 1 wherein the first header further comprises a first plurality of pads and defines leg placement positions for first ends of the first plurality of legs of the first stage of thermoelectric devices connected to the first plurality of pads.

3. The cascade thermoelectric module of claim 2 wherein the second header further comprises:
a second plurality of pads on the first surface of the second header, the second plurality of pads defining leg placement positions for second ends of the first plurality of legs of the first stage of thermoelectric devices connected to the second plurality of pads such that the first stage of thermoelectric devices are connected in series by the first and second pluralities of pads of the first header and the first surface of the second header, respectively; and
a third plurality of pads on the second surface of the second header, the third plurality of pads defining leg placement positions for first ends of the second plurality of legs of the second stage of thermoelectric devices connected to the third plurality of pads.

4. The cascade thermoelectric module of claim 3 wherein the third header further comprises a fourth plurality of pads and defines leg placement positions for second ends of the second plurality of legs of the second stage of thermoelectric devices connected to the fourth plurality of pads such that the second stage of thermoelectric devices are connected in series by the third and fourth pluralities of pads of the second surface of the second header and the third header, respectively.

5. The cascade thermoelectric module of claim 4 wherein:
the first plurality of pads comprises pads that each define areas for one of the first set of leg placement positions and one of the second set of leg placement positions for the first ends of the subset of the first plurality of legs and each further define areas for a leg placement position for the first end of an additional leg of the first plurality of legs;
the second plurality of pads comprises pads that each define an area for one of the first set of leg placement positions for the second end of one of the subset of the first plurality of legs, and an additional pad that defines areas for the second set of leg placement positions for the second ends of the subset of the first plurality of legs;
the third plurality of pads comprises pads that each define an area for one of the first set of leg placement positions for the first end of one of the subset of the second plurality of legs, and pads that each define an area for one of the second set of leg placement positions for the first end of one of the subset of the second plurality of legs; and
the fourth plurality of pads comprises pads that each define an area for one of the first set of leg placement positions and an area for one of the second set of leg placement positions for the second ends of the subset of the second plurality of legs and that each further define an area for a leg placement position for the second end of an additional leg of the second plurality of legs.

6. The cascade thermoelectric module of claim 5 wherein the second header comprises vias that electrically couple the pads that define the areas for the first leg placement positions on the first surface of the second header and the pads that define the areas for the first leg placement positions on the second surface of the second header such that, when the subsets of the first and second pluralities of legs are positioned in the respective first sets of leg placement positions, the first and second stages of thermoelectric devices are electrically coupled in series by the vias through the second header.

7. The cascade thermoelectric module of claim 1 wherein:
the first header further comprises positive and negative contact pads for the first stage of thermoelectric devices;
the second header further comprises positive and negative contact pads for the second stage of thermoelectric devices;
wherein, when the subsets of the first and second pluralities of legs are positioned in the respective second sets of leg placement positions, the cascade thermoelectric module is operated in a common power mode of operation by electrically coupling the positive contact pad of one of the first and second stages of thermoelectric devices to the negative contact pad of the other one of the first and second stages of thermoelectric devices.

8. The cascade thermoelectric module of claim 1 wherein the subsets of the first and second pluralities of legs are positioned in the respective first sets of leg placement positions such that the first and second stages of thermoelectric devices are electrically coupled in series.

9. The cascade thermoelectric module of claim 1 wherein the subsets of the first and second pluralities of legs are positioned in the respective second sets of leg placement positions such that the first and second stages of thermoelectric devices are electrically decoupled within the cascade thermoelectric module.

10. The cascade thermoelectric module of claim 1 further comprising the first plurality of legs and the second plurality of legs, wherein each of the first plurality of legs has equivalent first dimensions, and each of the second plurality of legs has equivalent second dimensions different from the first dimensions of the first plurality of legs.

11. The cascade thermoelectric module of claim 1 further comprising the first plurality of legs and the second plurality of legs, wherein a total number of the first plurality of legs is different than a total number of the second plurality of legs.

12. The cascade thermoelectric module of claim 1 further comprising the first plurality of legs and the second plurality of legs, wherein a total number of the first plurality of legs is different than a total number of the second plurality of legs such that the cascade thermoelectric module forms a pyramidal shaped structure.

13. A thermoelectric system comprising:
a cascade thermoelectric module, comprising:
a plurality of headers comprising a first header, a second header, and a third header,
the first header and a first surface of the second header configured to electrically connect a first plurality of legs to form a first stage of thermoelectric devices electrically connected in series, the first header and the first surface of the second header defining a first set of leg placement positions for a subset of the first plurality of legs and a second set of leg placement positions for the subset of the first plurality of legs;
a second surface of the second header and the third header configured to electrically connect a second plurality of legs to form a second stage of thermoelectric devices electrically connected in series, the second surface of the second header and the third header defining a first set of leg placement positions for a subset of the second plurality of legs and a second set of leg placement positions for the subset of the second plurality of legs; and
the second header being further configured such that:
the first and second stages of thermoelectric devices are electrically coupled in series when the subsets of the first and second pluralities of legs are positioned in the respective first sets of leg placement positions; and
the first and second stages of thermoelectric devices are electrically decoupled within the cascade thermoelectric module when the subsets of the first and second pluralities of legs are positioned in the respective second sets of leg placement positions; and
a control system configured to power the cascade thermoelectric module in accordance with one or more modes of operation.

14. The thermoelectric system of claim 13 wherein the subsets of the first and second pluralities of legs are positioned in the respective first sets of leg placement positions such that the first and second stages of thermoelectric devices are electrically coupled in series.

15. The thermoelectric system of claim 13 wherein the subsets of the first and second pluralities of legs are positioned in the respective second sets of leg placement positions such that the first and second stages of thermoelectric devices are electrically decoupled within the cascade thermoelectric module.

16. The thermoelectric system of claim 15 wherein the first header further comprises a set of contact pads configured to receive power from a first power source coupled to a positive one of the set of contact pads and a negative one of the set of contact pads, and the second header further comprises a set of contact pads configured to receive power from a second power source coupled to a positive one of the set of contact pads and a negative one of the set of contact pads, the thermoelectric system further comprising:
one or more external electrical connectors configured to electrically couple one of the set of contact pads of the first header and one of the set of contact pads of the second header to electrically couple the first and second stages of thermoelectric devices in series.

17. The thermoelectric system of claim 16 wherein the control system further comprises power control and switching circuitry configured to selectively activate or deactivate the one or more external electrical connectors in accordance with the one or more modes of operation.

18. The thermoelectric system of claim 17 wherein the control system further comprises a controller configured to select one of the one or more modes of operation to thereby provide a selected mode of operation and control the power control and switching circuitry to selectively activate or deactivate the one or more external electrical connectors in accordance with the one or more modes of operation.

19. The thermoelectric system of claim 18 wherein the selected mode of operation is selected from a group consisting of:
an external common power mode of operation in which:
the one or more external electrical connectors connect one of the set of contact pads of the first header and one of the set of contact pads of the second header to electrically couple the first and second stages of thermoelectric devices in series; and
the first and second stages of thermoelectric devices are powered by a common power source;
a first separate power mode of operation in which the first and second stages of thermoelectric devices are configured to be powered from a single power source in parallel; and
a second separate power mode of operation in which the first stage of thermoelectric devices and the second stage of thermoelectric devices are powered by distinct power sources.
